(19) United States
(12) Patent Application Publication
(10) Pub. No.: US 2016/0365317 A1
(43) Pub. Date: Dec. 15, 2016

(54) METHOD AND APPARATUS FOR FORMING EMI SHIELDING LAYERS ON SEMICONDUCTOR PACKAGES

(71) Applicant: TEL NEXX, Inc., Billerica, MA (US)

(72) Inventors: Arthur Keigler, Wellesley, MA (US); Stephen W. Into, Harvard, MA (US); Ramya Chandrasekaran, Acton, MA (US); Georgiy Seryogin, Watertown, MA (US); Daniel L. Goodman, Lexington, MA (US); Mani Sobhian, Chelmsford, MA (US)

(21) Appl. No.: 15/180,885

(22) Filed: Jun. 13, 2016

Related U.S. Application Data
(60) Provisional application No. 62/175,317, filed on Jun. 14, 2015.
(60) Provisional application No. 62/180,418, filed on Jun. 16, 2015.
(60) Provisional application No. 62/188,345, filed on Jul. 2, 2015.

(51) Int. Cl. H01L 23/552; H01L 21/56; H01L 21/48; H01L 23/498; H01L 23/31

(52) U.S. Cl. CPC H01L 23/552; H01L 23/49838; H01L 23/3114; H01L 21/485; H01L 21/4853; H01L 21/565

(57) ABSTRACT

A method and apparatus for EMI shielding of an electronic package is described. The method includes applying a patterned package support to a transport tray, and placing one or more electronic packages in aligned contact with one or more open features of the patterned package support such that a peripheral region of the electronic package contacts an upper surface of the patterned package support and a central region overhangs the open feature. The method further includes depositing one or more metal layers onto the one or more electronic packages and patterned package support, wherein the open features in the patterned package support allow metal layer deposition on the sidewalls of the one or more electronic packages and protect at least a portion of the underside of the one or more electronic packages.

### CROSS REFERENCE TO RELATED APPLICATIONS

The present application claims the benefit of U.S. Provisional Patent Application No. 62/175,317, filed on Jun. 14, 2015, entitled “METHOD AND APPARATUS FOR FORMING EMI SHIELDING LAYERS ON SEMICONDUCTOR PACKAGES,” which is incorporated herein by reference in its entirety. The present application claims the benefit of U.S. Provisional Patent Application No. 62/180,418, filed on Jun. 16, 2015, entitled “METHOD AND APPARATUS FOR FORMING EMI SHIELDING LAYERS ON SEMICONDUCTOR PACKAGES,” which is incorporated herein by reference in its entirety. The present application claims the benefit of U.S. Provisional Patent Application No. 62/188,345, filed on Jul. 2, 2015, entitled “METHOD AND APPARATUS FOR FORMING EMI SHIELDING LAYERS ON SEMICONDUCTOR PACKAGES,” which is incorporated herein by reference in its entirety.

### BACKGROUND OF THE INVENTION

This disclosure relates to packaging techniques for packing and shielding of semiconductor devices such as integrated circuits. Electrical insulating packaging materials are used to encapsulate IC (Integrated Circuits) chips inside semiconductor chip packages. With the drive toward more compact packages, metal layers for electromagnetic interference (EMI) shielding are directly adhered to the package either by coating processes or vapor deposition processes, such as PVD (Physical Vapor Deposition) processing. PVD processing has the advantage of providing an extremely pure, high-conductivity metallic shield, which reduces the EMI layer thickness. After the insulating package is properly prepared, for example using a vacuum pre-heating step followed by a plasma pre-treatment step, PVD processing typically provides well-adhered metal layers with excellent EMI shielding properties.

### SUMMARY

Electronic packaging molding materials are primarily composed of cured epoxy which softens at elevated temperatures, setting a maximum allowable temperature during processing. The vacuum pre-heat, surface pre-treatment and PVD process steps deposit heat in the package. For reasons of productivity, it is desirable to operate the pre-treatment and deposition steps at high system power. A method for forming EMI shielding layers on semiconductor packages must provide sufficient cooling to prevent the package from exceeding its maximum allowed temperature when subject to high power processing.

In later fabrication steps, the package is soldered to a substrate. The reliability of soldering may be reduced if any contaminants are left on the package electrical contacts. It is therefore preferable that the package's electrical contacts not touch any material during processing.

Areas of the package which typically require EMI shielding include the top and sides. The base of the package contains electrical contacts, which are usually formed as array of pads or balls, which project from the package and which must be protected from metal deposition to prevent electrical shorting.

The EMI shielding quality of sputtered films depends on the purity of the deposited metal, because contaminants incorporated into the film can increase the resistance. It is desirable for polymeric materials used during EMI shielding to be vacuum compatible, possessing low out-gassing rates over the full processing temperature range, in order to prevent film contamination. In addition, it is desirable to minimize the surface area of polymeric materials which are in contact with the plasma environment which exists in PVD chambers, because this may also lead to outgassing and film contamination.

Conventional techniques for forming EMI shielding layers on packages have various deficiencies. One conventional technique is to create a temporary protective coating on electrical contacts prior to EMI shield deposition. The temporary protective coating is subsequently removed by a heating step. Removing such a temporary protective coating, however, is costly and difficult to completely remove without leaving residue. Other conventional techniques include shielding electrical contacts using pockets formed in trays. A liquid adhesive can be used, which is heat-cured in place. FIG. 1A shows a typical geometry for such a method. In FIG. 1A, package 100 has been sputter coated with EMI metal shielding layer 101. Also shown are electrical contacts 103, liquid adhesive 102, supporting tray 104 with pocket 106 and corner 105. Details at corner 105 are shown in FIG. 1B. After processing, full thickness deposition in corner 105 covers liquid adhesive 102 and the package sidewall 110. When the adhesive is removed from the package during the final process step, the metal coating at the bottom position of the package sidewall 110 is incomplete or not well defined. Metal in corner 105 can remain bonded to the adhesive, and tear away from the package at location 110, leaving a poorly adhered layer and potentially a hanging and/or poorly attached metal fragment.

Techniques herein include methods and systems for EMI shielding that overcome conventional challenges. Techniques include EMI shielding that can cover an entire package sidewall, and that provides a well-defined and smooth deposition ending interface. Embodiments of the invention relate generally to partially encapsulating a package with a conductive layer, and, more specifically, to applying electromagnetic interference (EMI) shielding to packaged integrated circuits (ICs).

According to one embodiment, a method for EMI shielding of an electronic package is described. The method includes applying a patterned package support to a transport tray. The patterned package support defines one or more first open features and defines one or more second open features. One or more electronic packages are placed on the patterned package support in alignment with the one or more first open features of the patterned package support such that a peripheral region of the one or more electronic packages contacts an upper surface of the patterned package support and a central region of the electronic package overlies the one or more first open features. One or more metal layers is deposited on the one or more electronic packages and the patterned package support. The one or more second open features in the patterned package support enable metal layer deposition on sidewalls of the one or more electronic packages.

According to another embodiment, an apparatus for EMI shielding of an electronic package is described. The apparatus includes a patterned package support including a patterned laminate comprised of a core carrier layer having an upper surface and a lower surface, a first adhesion layer applied to the upper surface and a second adhesion layer applied to the lower surface. The patterned package support is configured to be applied to an upper surface of a transport tray. The patterned package support can have one or more first open features configured to receive the one or more electronic packages such that a peripheral region of the electronic package contacts an upper surface of the patterned package support and a central region is in alignment with a given first open feature.

According to yet another embodiment, an apparatus for EMI shielding of an electronic package is described. The apparatus includes a transport tray having an upper surface. A; and a patterned package support is applied to the transport tray and configured to support one or more electronic packages. The patterned package support includes a patterned laminate composed of a core carrier layer having an upper surface and a lower surface. A first adhesion layer applied to the upper surface and a second adhesion layer applied to the lower surface. The patterned package support has one or more open features configured to receive the one or more electronic packages such that a peripheral region of the electronic package contacts an upper surface of the patterned package support and a central region overhangs the open feature.

Of course, the order of discussion of the different steps as described herein has been presented for clarity sake. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present invention can be embodied and viewed in many different ways.

Note that this summary section does not specify every embodiment and/or incrementally novel aspect of the present disclosure or claimed invention. Instead, this summary only provides a preliminary discussion of different embodiments and corresponding points of novelty over conventional techniques. For additional details and/or possible perspectives of the invention and embodiments, the reader is directed to the Detailed Description section and corresponding figures of the present disclosure as further discussed below.

### BRIEF DESCRIPTION OF THE DRAWINGS

A more complete appreciation of various embodiments of the invention and many of the attendant advantages thereof will become readily apparent with reference to the following detailed description considered in conjunction with the accompanying drawings. The drawings are not necessarily to scale, with emphasis instead being placed upon illustrating the features, principles and concepts.

FIGS. 1A-1B illustrate a conventional technique for forming EMI shielding on an IC package.

FIGS. 2A and 2B illustrate various types of IC packages.

FIGS. 3A-3C illustrate methods of forming EMI shielding on an IC package according to embodiments disclosed herein.

FIGS. 4A-4D illustrate methods of forming EMI shielding on an IC package according to embodiments disclosed herein.

FIG. 5 illustrates a method of forming EMI shielding on an IC package according to embodiments disclosed herein.

FIGS. 6A-6C illustrate methods of forming EMI shielding on an IC package according to embodiments disclosed herein.

FIG. 7 provides exemplary data depicting an EMI shielding application.

FIG. 8 provides exemplary data depicting IC package cooling.

FIG. 9 provides a flow chart depicting a method of forming EMI shielding on an IC package according to embodiments disclosed herein.

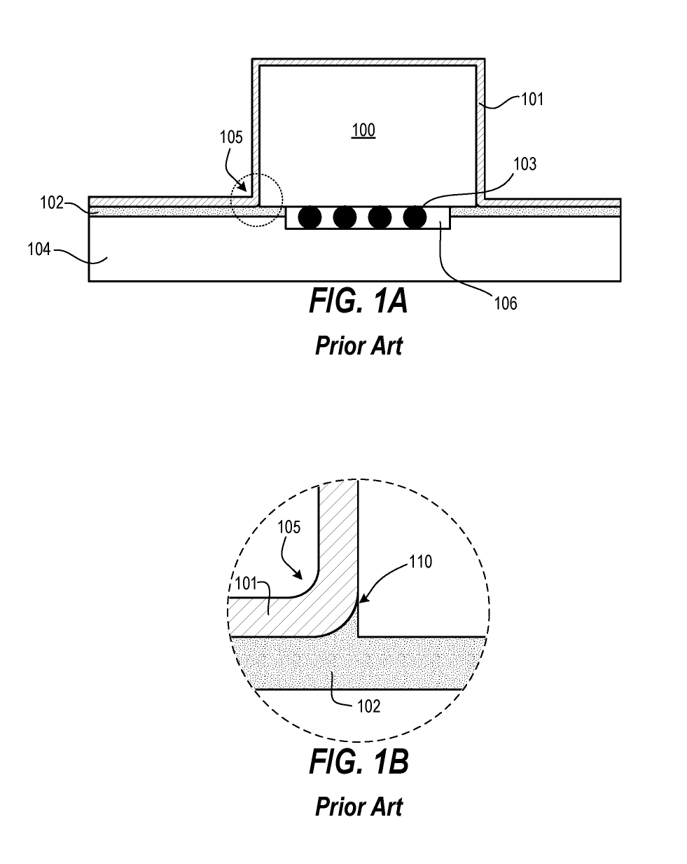

### DETAILED DESCRIPTION

Techniques herein include methods for partially encapsulating a package with a conductive layer, and, more specifically, methods and apparatus of applying electromagnetic interference (EMI) shielding to packaged integrated circuits (ICs) are described in various embodiments. Techniques include improved methods and systems for EMI shielding of electronic packages. Techniques herein use a patterned package support (PPS) which supports and can cool electronic packages during application (such as sputter deposition) of EMI conductive or metal films. The patterned package support is a composite with adhesive and thermally conductive properties. The geometry and material of the patterned package support overcomes limitations of conventional methods.

Accordingly, methods and apparatus for forming EMI shielding on electronic packages is described herein with reference to the accompanying drawings

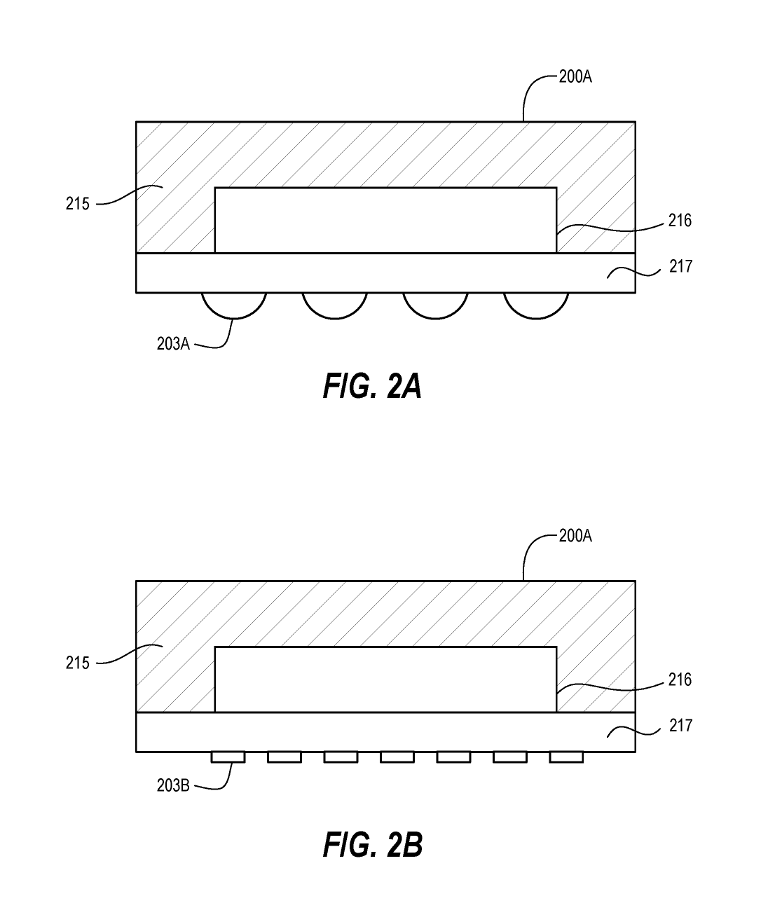

A typical semiconductor chip package is shown in FIG. 2A. An electronic package 200A includes an IC chip 216 mounted to a substrate 217 encapsulated in an insulating material 215. The insulating material 215 can be, for example, an epoxy molding compound. The electronic package 200A can be rectangular and can include a top, four sides, and a bottom. Electrical connections on the bottom can be package balls 203A if the package is of the Ball Grid Array (BGA) type, or can be flat connective pads 203B if the package is of the Land Grid Array (LGA) type, as shown in FIG. 2B.

In order to shield a given package from electromagnetic interference (EMI), the top surface and sidewalls of the electronic package can be coated with one or more metals layers. Metal layers can include copper and stainless steel, but other metals can be used. Several embodiments prevent coating of electrical connections on the bottom of the package, thereby preventing shorting of the electrical contacts.

Although techniques herein are described as using sputtering by physical vapor deposition (PVD), other vacuum metal deposition methods, such as evaporation, can be used. Prior to PVD deposition, the package can be heated under vacuum to remove trapped gas and absorb volatile species including water vapor. The surface of the package can also be prepared using a plasma pre-treatment step. A system which is capable of performing package de-gassing, surface preparation and EMI shield sputter coating is the APOLLO™ sputter tool made by TEL NEXX, Inc., and described in U.S. Pat. Nos. 6,328,858 and 6,530,733. Additional details for a method of improving the adhesion of EMI shielding layers to packages are disclosed in US Application Publication No. 2015/0044871.

In some embodiments, electronic packages are transported through the PVD system, wherein the packages have been previously placed on transport trays, typically using a pick-and-place machine. A working surface of the transport tray can be flat or have pockets to prevent contact with the package balls 203A or flat connective pads 203B. In one embodiment, the underside of the transport tray has features which align with features of the processing tool to allow transport. Such features are described in U.S. Pat. No. 6,821,912. In another embodiment, the transport tray can be placed onto a secondary support tray which contains the alignment features.

Significant heat can be deposited or transferred into the package during processing, and so the package can be cooled to maintain its temperature below a maximum allowable value. Cooling can be accomplished by thermal contact with the transport tray, which itself can be cooled. Tray cooling is accomplished by contact of the transport tray, also known as a substrate processing pallet, with a water-cooled support plate, though other cooling mechanisms can be used. Substrate processing pallet designs for optimal cooling of substrates are described in US Application Publication No. 2008/0220622.

In some fabrication schemes, placing packages directly on a cool transport tray is not sufficient to provide cooling at high processing power. In practice, the electronic package and the transport tray may not be perfectly flat, and there may be insufficient gas in the chamber during processing to effectively conduct heat between the surfaces.

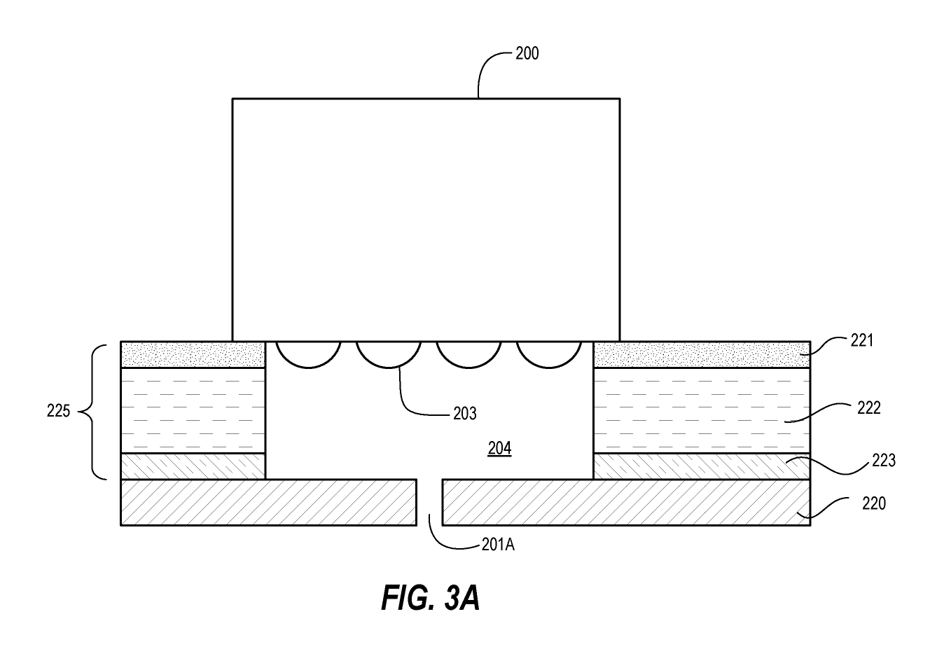

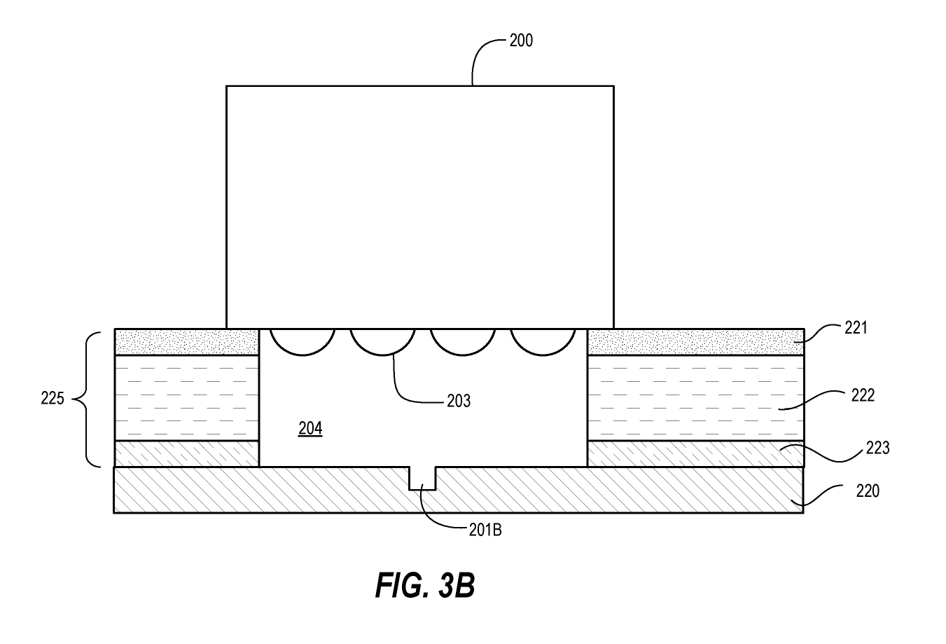

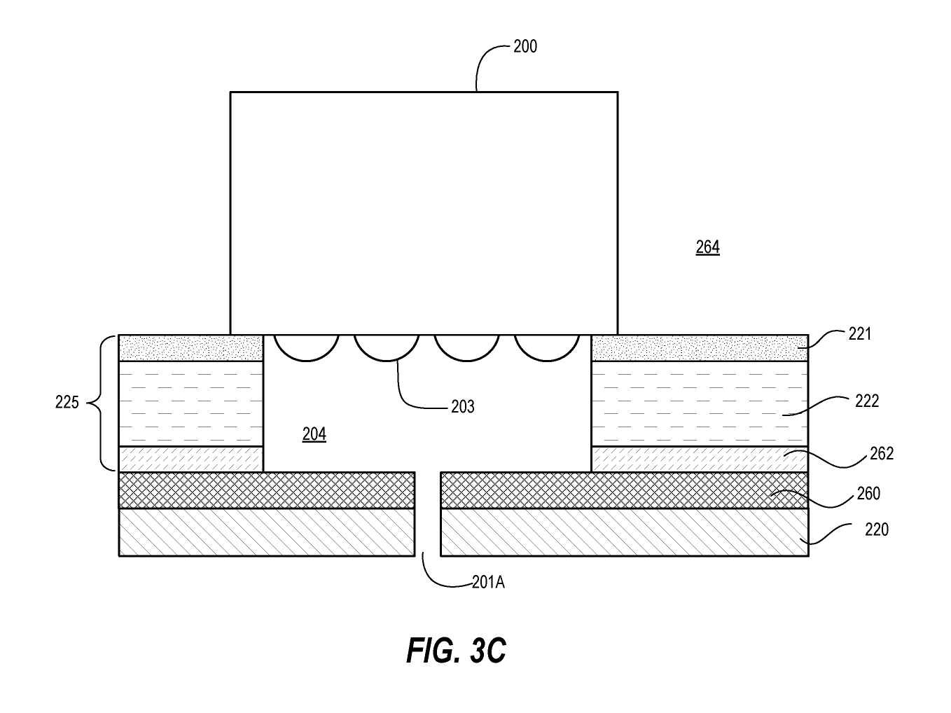

An example patterned package support 225 is described, as shown in FIG. 3A, to provide sufficient thermal contact cooling and to maintain the electronic package in proper orientation on the transport tray. The patterned package support 225 includes a patterned laminate composed of a core carrier layer 222 having an upper surface and a lower surface. A first adhesion layer 221 is applied to the upper surface and a second adhesion layer 223 is applied to the lower surface. The first and second adhesion layers 221 and 223 can include a pressure-sensitive adhesive (PSA). The PSA layers enable good thermal contact to the transport tray 220 and to a portion of the underside of electronic package 200. PSA materials, such as acrylic-type PSA or silicone-type PSA, are commercially available from 3M and Shin-Etsu. The core carrier layer 222 (central layer) can be fabricated of a plastic, including polycarbonate or polyethylene terephthalate, such as MYLAR™. The patterned package support can be removed and re-applied to the transport tray.

The thickness for the first adhesion layer 221 can range from 10 to 250 microns (0.4 to 10 mils), or 10 to 50 microns. The thickness for the second adhesion layer 223 can range from 10 to 250 microns (0.4-10 mils), or 25 to 100 microns. The thickness for the core carrier layer 222 can range from 15 to 750 microns (0.7-30 mils), or 50 to 250 microns. A cutout in the patterned package support 225, or first open feature 204, prevents touching of electrical contacts 203. In other words, the patterned package support defines a pocket or cavity over which electrical connections can be placed. Vacuum venting of first open feature 204, or the region below the package, can be accomplished with a vacuum vent hole 201A (FIG. 3A) or vacuum vent channel 201B (FIG. 3B) in the transport tray 220, which accesses or aligns with first open feature 204 in the patterned package support 225. Alternatively, such access can be accomplished using slits (not shown) in the core carrier layer 222 and first adhesion layer 221. Vacuum venting features can include through-holes formed through the transport tray.

Referring now to FIG. 3C, the transport tray 220 can optionally include an electrostatic chuck (ESC) 260 that can be used to secure the patterned package support 225, or variations thereof, to the transport tray 220. An exemplary embodiment, also known as a transport pallet, is described in US Pub. 2008/0220622 and is incorporated by reference. The patterned package support 225 can include the core carrier layer 222 disposed between the first and second adhesion layers. However, two or more first and second adhesion layers, may not be required in other embodiments.

Continuing with FIG. 3C, one of the PSA layers (second adhesion layer 223 from the FIG. 3A embodiment) can be replaced with a conductive layer 262. The conductive layer 262 can comprise any conductive material. Example materials include, but are not limited to, metals (e.g., aluminum, copper, etc.) or carbon (e.g., graphene). The conductive layer 262 can have a thickness with a range of 0.01-0.5 um. The thickness can be optimized based, at least in part, on having a sufficiently high conductivity to provide electrostatic adhesion between the patterned package support 225 or the core carrier layer 222 and the ESC 260.

In one embodiment, desirable electrostatic adhesion can include maintaining a pressure differential between the first open feature 204 and the surrounding vacuum chamber 264, such that a leak rate between the first open feature 204 and the surrounding vacuum chamber 264 is minimal or near zero. In another instance, desirable electrostatic adhesion can be demonstrated by maintaining the pressure within the first open feature 204 at a higher pressure than the surrounding vacuum chamber. In one embodiment, the transport tray 220 and ESC 260 can also include a vacuum vent hole 201A, a vacuum vent channel 201B, or combination thereof. The vacuum vent holes 201A or vacuum vent channels 201B can correspond with the first open feature 204 distributed throughout the transport tray 220 and can be used to evacuate or purge the open feature prior to engaging the ESC 260. Vacuum vent holes 201A or vacuum vent channels 201B or can also be used to prevent the electronic package 200 from being detached from the patterned package support 225 during pump down of the surrounding vacuum chamber 264 due to a pressure differential.

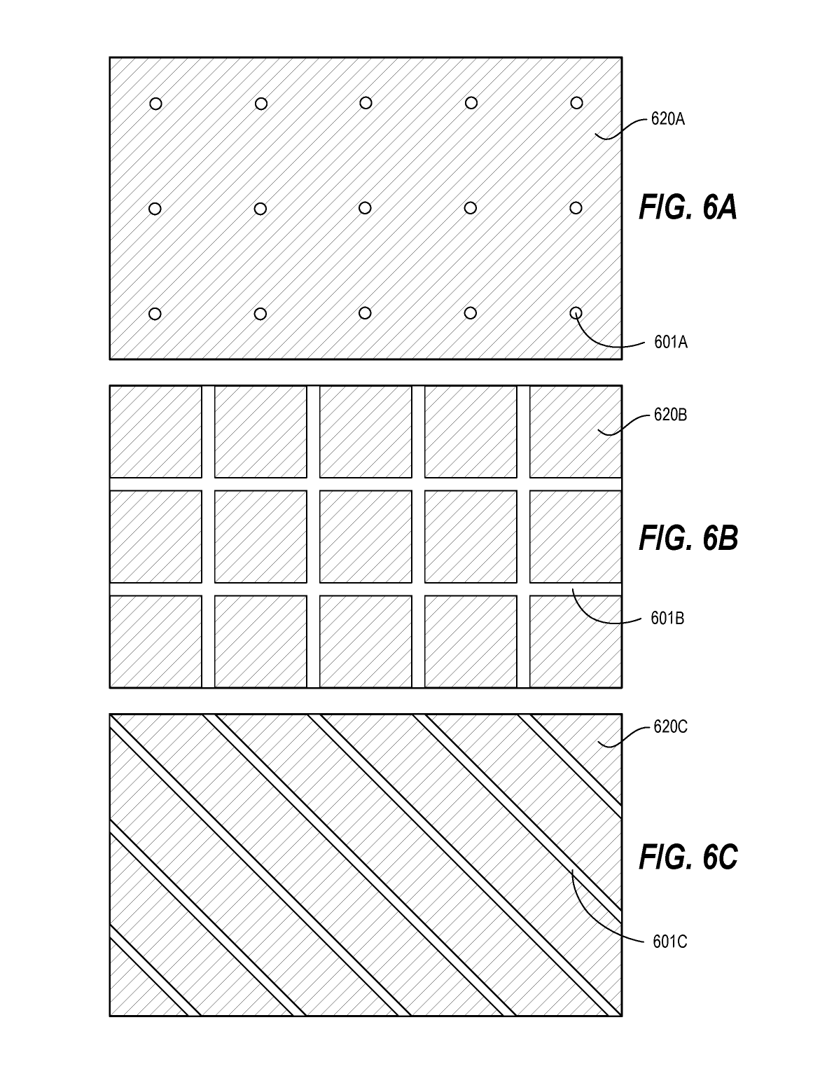

In alternative embodiments, as shown in FIGS. 6A-6C, a transport tray 620A can include plural vent holes 601A (FIG. 6A), or a transport tray 620B can include plural vent channels 601B (FIG. 6B), or a transport tray 620C can include plural vent channels 601C (FIG. 6C). The transport tray 220, of any embodiment, can be fabricated of, for example, aluminum.

Patterned package support 225 can be fabricated using lamination and cut-out techniques. For example, PSA can be applied to the core layer. The lower release layer can be removed allowing application of the patterned package support 225 to the transport tray 220, and the upper release layer can be removed allowing placement and adhesion of electronic packages on the patterned package support 225. Cut-outs, including through-cuts, or first open feature 204 can be fabricated using mechanical die cutting, laser ablation, water jet processing, etc.

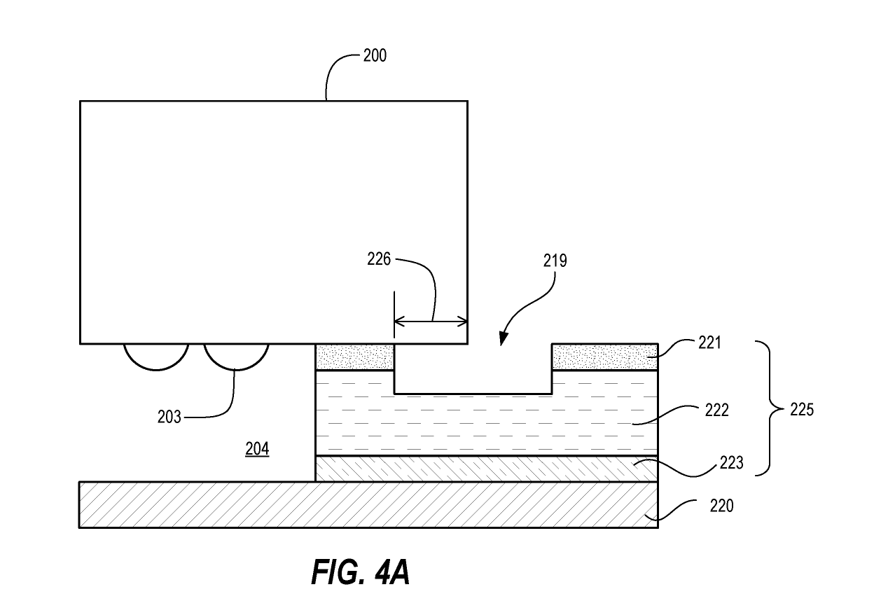

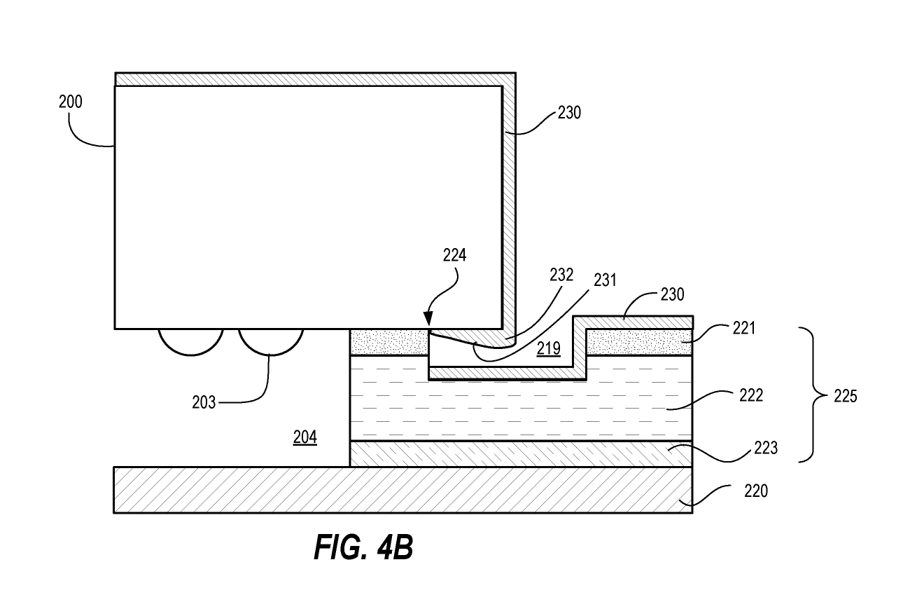

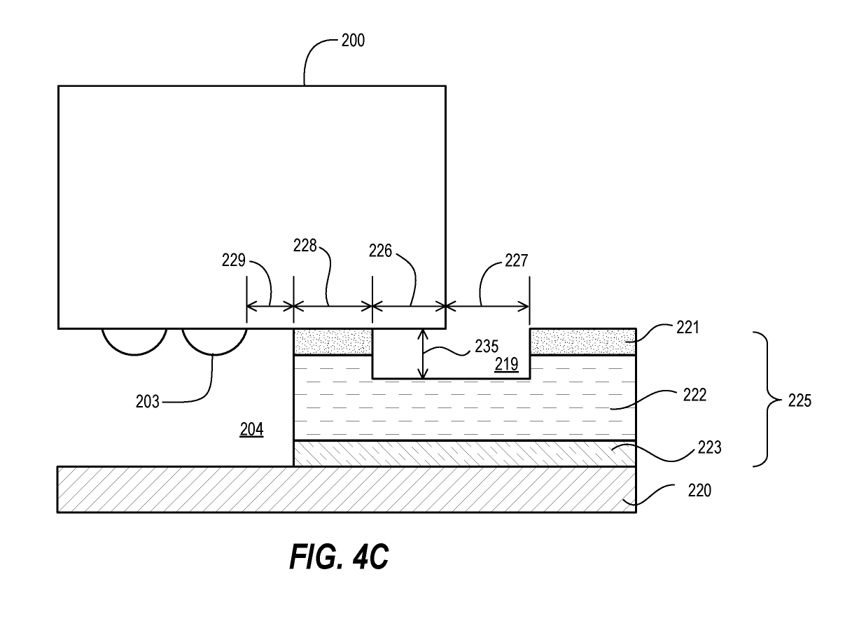

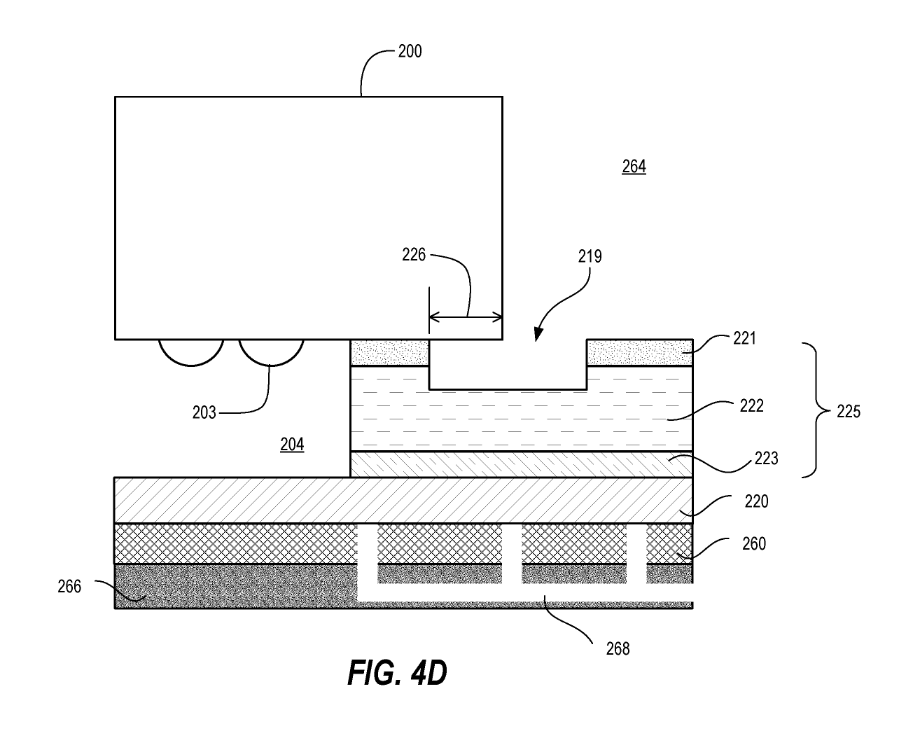

FIG. 4A shows an additional patterning of the patterned package support 225 which moves the patterned package support landing zone (region where the first adhesion layer 221 contacts the underside of the electronic package 200) underneath the electronic package 200, at a recess 226 from the package edge. This recess 226 is accomplished by patterning of a Deposition Dump Zone or second open feature 219. The patterning or partial cut of the patterned package support 225 including removal of material to create the second open feature 219 can be done using conventional conversion processes, including mechanical die cutting, laser ablation, water jet processing techniques, etc.

FIG. 4B shows the electronic package 200 and the patterned package support 225 after EMI shielding layer 230 has been applied. Wrap-around deposition due to metal scattering from neutral atoms during PVD sputtering results in deposition around corner 232 and the tapered underside deposition profile 231. The deposition can be zero or non-zero at intersection 224. Nevertheless, any deposition at intersection 224 is sufficiently reduced to achieve a clean interface when the patterned package support 225 and electronic package 200 are separated from each other after processing.

Referring to FIG. 4C, the patterned package support 225 has a landing zone whose landing zone width 228 is sufficient to provide the necessary electronic package cooling and whose recess from the recess 226 is sufficient so that when the electronic package is detached from the patterned package support 225, the edge interface is well-defined and smooth. The patterned package support 225 has second open feature 219 that is partial cut open having depth 235 that is sufficiently shallow to minimize the thickness of the tapered underside deposition profile 231, but sufficiently deep to allow for manufacturing tolerance variations such that deposition thickness of the tapered underside deposition profile 231 is never in contact with the base or bottom of the second open feature 219. These requirements lead to a landing zone width 228 which can range from 100 to 1500 microns (4-60 mils), or 50 to 200 microns. A recess from the recess 226 can range from 25 to 2000 microns (1-80 mils). Second open feature 219 can have a depth 235 that ranges from 25 to 500 microns (1-20 mils), or 25 to 100 microns. Second open feature 219 can have a width 227 that ranges from 50 to 2500 microns (2-100 mils), or 30 to 150 microns. A spacing 229 between an electrical contact and an edge of the open feature can exceed 200 microns.

Referring to FIG. 4D, transport tray 220 can rest on transport pallet 266 that can include ESC 260 that can be disposed between the transport tray 220 and the transport pallet 266. The transport tray 220 can support the patterned package support 225 or variation thereof. The ESC 260 can be used to enable electrostatic adhesion between the transport tray 220 and the transport pallet 266 to maintain a pressure difference between the first open feature 204 and the surrounding vacuum chamber 264. In this embodiment, the transport tray 220 can be cooled using a backside gas manifold 268 that can be incorporated into the transport pallet 266. The patterned package support 225 can be cooled by providing gas through the backside gas manifold 268 that can be in fluid communication with a gas source (not shown). Details of backside gas cooling in transport pallet 266 are also included in US Pub. 2008/0220622 and incorporated by reference. The backside cooling or backside gas manifold 268, however, is an optional embodiment.

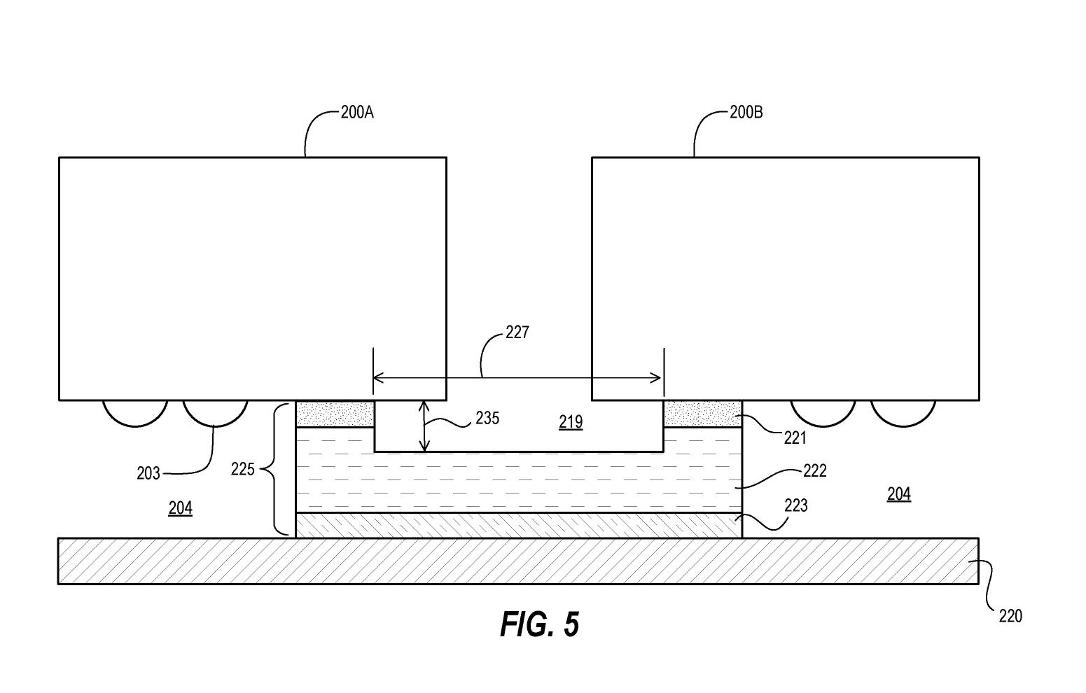

Referring now to FIG. 5, an alternate embodiment improves sidewall deposition and reduces surface are the first adhesion layer 221 in contact with electronic packages 200A and 200B and exposed to the plasma environment. In this embodiment, the patterned package support 225 can be patterned to remove upper PSA layer and a portion of core carrier layer 222 in the region between adjacent electronic packages 200A and 200B. The depth 235 of the second open feature 219 in this embodiment can range from 25 to 500 microns (1-20 mils) and the width 227 of the second open feature 219 can range from 250-3500 microns (10-140 mils).

The PSA material for the first and second adhesion layers 221 and 223 benefits from having good vacuum compatibility, with less than a total mass loss of 1% and a maximum collectable volatile material of 0.1% when measured using ASTM Standard E 595-90. The PSA material for the upper layer, first adhesion layer 221, is selected to have sufficiently low tack, which allows a pick-and-place machine to easily remove the package. The PSA material for the first adhesion layer 221 can be selected to have a composition that leaves no residue on the underside of the package after removal. The PSA material of the second adhesion layer 223 can be selected to have sufficiently low tack to easily allow peeling of the patterned package support 225 from the transport tray 220. The first and second adhesion layers 221 and 223 can be composed of acrylate, silicone or other chemistry, and can optionally be of the same or different compositions.

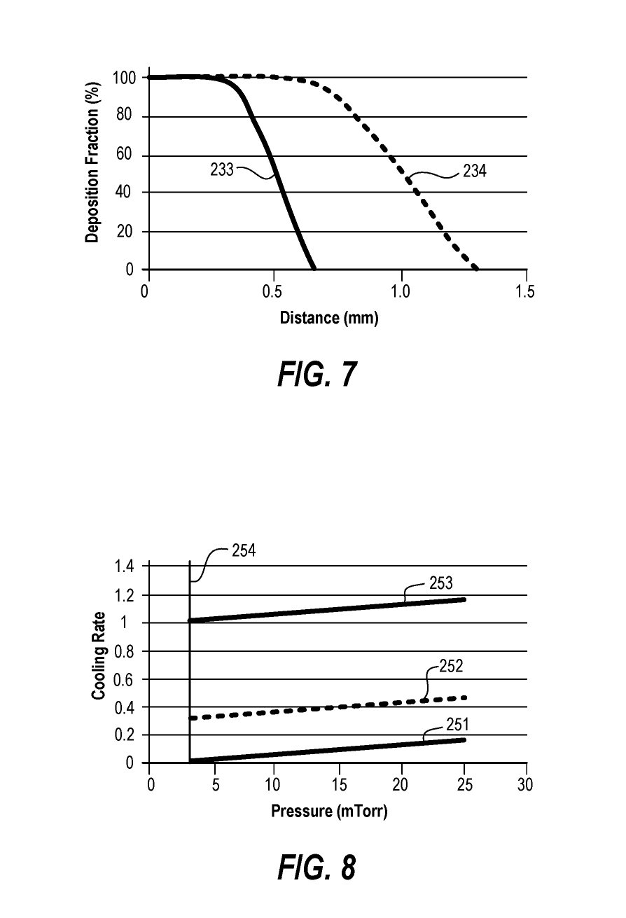

Referring again to FIG. 4B, the wrap-around deposition of the tapered underside deposition profile 231 is the full thickness near the corner 232 (bottom corner) of electronic package 200 and decreases with distance from the corner. FIG. 7 includes curves 233 and 234 which illustrate two possible profiles for wrap around deposition of the tapered underside deposition profile 231, where the abscissa is distance measured from the package corner and the ordinate is deposition normalized to full thickness. The wrap-around deposition scale length increases with the PVD operating gas pressure and with depth 235 (FIG. 5). Curve 234 illustrates a longer scale length, corresponding to a higher PVD operating gas pressure and/or a larger depth 235. Curve 233 illustrates a shorter scale length, corresponding to a lower PVD operating gas pressure and/or a smaller depth.

Referring now to FIG. 8, three curves for package cooling rate versus PVD operating gas pressure are shown. Curve 251 represents cooling by the operating gas pressure alone. Curve 252 represents cooling by a combination of PVD process gas conduction and a landing zone width 228, for example 4C, that is narrow for the patterned package support. Curve 253 represents cooling by a combination of process gas conduction and a wider patterned package support landing zone width 228, for example 4C. As shown in FIG. 7, there is a minimum operating pressure 254 required to sustain PVD sputtering plasma discharge.

Curves for wrap-around deposition of the tapered underside deposition profile 231 and cooling rate 255 for specific package dimensions and geometry of patterned package support can be determined by measurement or by modeling. Such curves, together with knowledge of the package geometry and maximum allowed temperature, determine the maximum PVD deposition rate for a particular patterned package support design. Conversely, for a given package geometry and desired PVD deposition rate less than a maximum value, there exists an optimal patterned package support structure and operating gas pressure which provides maximum pick-and-place tolerances, sufficient cooling, and a clean interface when the patterned package support is separated from the package after processing.

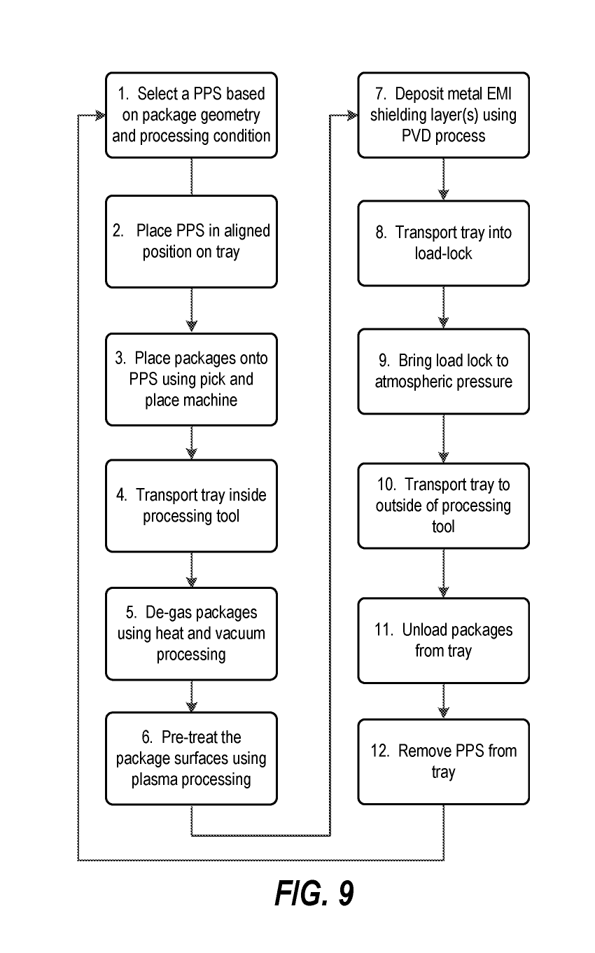

An example process flow, according to an embodiment herein, is shown in FIG. 9. Pre-process steps include the design and manufacture of patterned package support for all expected package geometries and processing conditions. Processing steps shown include, but are not limited to, the following: (1) Selecting of the patterned package support corresponding to the package being processed; (2) Placing the patterned package support onto the tray (The patterned package support position will be set by alignment features on the tray, such as pins, which project into holes in the patterned package support); (3) Placing the packages onto aligned positions on the patterned package support using a pick-and-place machine, using alignment features provided on the tray and/or on the patterned package support; (4) Transporting the transport tray into the processing tool; (5) De-gassing the packages using vacuum and heat processing; (6) Pre-treating the package surfaces with plasma processing for improved EMI film adhesion; (7) Depositing one or more EMI metal shielding layers using PVD processing; (8) Transporting the transport tray and packages into the load-lock; (9) Bringing the system to atmospheric pressure, which can also include tray cooling; (10) Transporting the transport tray and packages from the load-lock to outside the tool; (11) Unloading the packages from the transport tray using a pick-and-place machine or manually; (12) Removing the patterned package support from the transport tray, such as by peeling the patterned package support as a single assembly from the tray.

Accordingly, one embodiment includes a method for electromagnetic interference shielding of an electronic package. A patterned package support is applied to a transport tray. The patterned package support defines one or more first open features and defines one or more second open features. One or more electronic packages are placed on the patterned package support in alignment with the one or more first open features of the patterned package support such that a peripheral region of the one or more electronic packages contacts an upper surface of the patterned package support and a central region of the electronic package overlies the one or more first open features. One or more metal layers is deposited on the one or more electronic packages and the patterned package support. The one or more second open features in the patterned package support enable metal layer deposition on sidewalls of the one or more electronic packages.

The one or more second open features in the patterned package support can further enable metal layer deposition on an edge portion of an underside of the one or more electronic packages. Each of the one or more electronic packages can have an edge region that contacts a top surface of the patterned package support, and can have one or more electrical contacts which face the one or more first open features provided by the patterned package support. The patterned package support can further include one or more second open features. Each of the one or more second open features partially extends through the patterned package support and completely surrounds at least one of the one or more open features such that an edge portion of an underside of the one or more electronic packages overhangs the one or more second open features. In other words, there is an open space immediately below lower edges of the package that enables material to be fully deposited on the package sidewall and can include some deposition on an uncovered underside portion of the package. Alternatively, a size of at least one of the one or more second open features can exceed a spacing distance between sidewalls of adjacent electronic packages such that the adjacent electronic packages have an edge portion that overhangs a common second feature.

Another embodiment includes an apparatus for EMI shielding of an electronic package. This can include a transport tray and a plurality of microelectronic devices arranged around the transport tray. A patterned package support is disposed between the transport tray and the microelectronic devices. The patterned package support comprises a core carrier layer having a first surface and a second surface. A first adhesion layer is disposed on the first surface, and a second adhesion layer disposed on the second surface. The second adhesion layer, the first adhesion layer, and the core carrier layer can be arranged to enable fluid communication between the microelectronic devices and the transport tray. An electrostatic chuck can be coupled to the transport tray. The electrostatic chuck being opposite the patterned package support. The apparatus can include a cooling manifold being in fluid communication that is in fluid communication with the transport tray and a gas source

Another apparatus for EMI shielding of an electronic package includes a transport tray, a plurality of microelectronic devices arranged around the transport tray, and a patterned package support disposed between the transport tray and the microelectronic devices. The patterned package support comprises a core carrier layer having a first surface and a second surface, and an adhesion layer disposed on the first surface. A conductive layer is disposed on the second surface. The conductive layer, the adhesion layer, and the core carrier layer being in fluid communication with the microelectronic devices and the transport tray. The conductive layer can have a thickness, for example, between about 0.01 μm and 0.5 μm. An electrostatic chuck can be disposed between the conductive layer and the transport tray.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Reference throughout this specification to “one embodiment” or “an embodiment” means that a particular feature, structure, material, or characteristic described in connection with the embodiment is included in at least one embodiment of the invention, but does not denote that they are present in every embodiment. Thus, the appearances of the phrases “in one embodiment” or “in an embodiment” in various places throughout this specification are not necessarily referring to the same embodiment of the invention. Furthermore, the particular features, structures, materials, or characteristics may be combined in any suitable manner in one or more embodiments. Various additional layers and/or structures may be included and/or described features may be omitted in other embodiments.

“Package”, as used herein, generically refers to the object being processed in accordance with the invention. The package may include any electronic device, electro-mechanical device, electro-optical device, etc., that has been insulated and packaged, and that requires at least partial application of a conductive layer or EMI shielding layer to an exterior surface. Examples include integrated circuits (ICs) for use in computers, radio frequency (RF) devices, mobile devices, etc.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “target substrate” as used herein generically refers to an object being processed in accordance with the invention. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

Those skilled in the art will also understand that there can be many variations made to the operations of the techniques explained above while still achieving the same objectives of the invention. Such variations are intended to be covered by the scope of this disclosure. As such, the foregoing descriptions of embodiments of the invention are not intended to be limiting. Rather, any limitations to embodiments of the invention are presented in the following claims.

1. A method for electromagnetic interference shielding of an electronic package, comprising:
applying a patterned package support to a transport tray, the patterned package support defining one or more first open features and defining one or more second open features;
placing one or more electronic packages on the patterned package support in alignment with the one or more first open features of the patterned package support such that a peripheral region of the one or more electronic packages contacts an upper surface of the patterned package support and a central region of the electronic package overlies the one or more first open features; and
depositing one or more metal layers on the one or more electronic packages and the patterned package support, wherein the one or more second open features in the patterned package support enable metal layer deposition on sidewalls of the one or more electronic packages.

2. The method of claim 1, wherein the one or more second open features in the patterned package support further enable metal layer deposition on an edge portion of an underside of the one or more electronic packages.

3. The method of claim 1, wherein each of the one or more electronic packages has an edge region that contacts a top surface of the patterned package support, and has one or more electrical contacts which face the one or more first open features provided by the patterned package support.

4. The method of claim 1, wherein the patterned package support includes a patterned laminate composed of a core carrier layer having an upper surface and a lower surface, a first adhesion layer applied to the upper surface and a second adhesion layer applied to the lower surface.

5. The method of claim 1, further comprising:
providing vacuum venting features in the transport tray to permit vacuum venting of the one or more open features formed through the patterned package support.

6. The method of claim 1, wherein the patterned package support further includes one or more second open features, each of the one or more second open features partially extending through the patterned package support and completely surrounding at least one of the one or more open features such that an edge portion of an underside of the one or more electronic packages overhangs the one or more second open features.

7. The method of claim 6, wherein a size of at least one of the one or more second open features exceeds a spacing distance between sidewalls of adjacent electronic packages such that the adjacent electronic packages have an edge portion that overhangs a common second feature.

8. The method of claim 1, further comprising:
removing the patterned package support from the transport tray; and
re-applying a second patterned package support to the transport tray.

9. An apparatus for EMI shielding of an electronic package, comprising:
a patterned package support including a patterned laminate comprised of a core carrier layer having an upper surface and a lower surface, a first adhesion layer applied to the upper surface and a second adhesion layer applied to the lower surface, the patterned package support configured to be applied to an upper surface of a transport tray; and
wherein the patterned package support has one or more first open features configured to receive the one or more electronic packages such that a peripheral region of the electronic package contacts an upper surface of the patterned package support and a central region is in alignment with a given first open feature.

10. The apparatus of claim 9, wherein the patterned package support has one or more second open features wherein the one or more second open features in the patterned package support enable metal layer deposition on an edge portion of an underside of the one or more electronic packages.

11. The apparatus of claim 9, wherein each of the one or more electronic packages has an edge region that contacts a top surface of the patterned package support, and has one or more electrical contacts which face the one or more first open features provided by the patterned package support.

12. The apparatus of claim 11, wherein the core carrier layer is comprised of plastic, polycarbonate or polyethylene terephthalate; and
wherein the first adhesion layer and the second adhesion layer are pressure-sensitive adhesives.

13. The apparatus of claim 11, wherein a thickness of the first adhesion layer ranges from 10 microns to 50 microns, and wherein a thickness of the second adhesion layer ranges from 25 microns to 75 microns, and wherein a thickness of the core carrier layer ranges from 50 microns to 250 microns.

14. The apparatus of claim 9, wherein the one or more second open features is a continuous cut-out through the patterned package support.

15. The apparatus of claim 9, wherein the patterned package support further includes one or more second open features, each of the one or more second open features extending through the first adhesion layer and extending partially into the core carrier layer and completely surrounding at least one of the one or more first open features such that an edge portion of an underside of the one or more electronic packages overhangs the one or more second open features.

16. The apparatus of claim 9, further comprising a transport tray having an upper surface, wherein the patterned package support is configured to be removed from the transport tray and re-applied to the transport tray.

17. The apparatus of claim 16, wherein the transport tray further comprises:
one or more vacuum venting features formed in the upper surface of the transport tray to permit vacuum venting of the one or more open features formed through the patterned package support.

18. The apparatus of claim 17, wherein the one or more vacuum venting features include a through-hole formed through the transport tray.

19. The apparatus of claim 9, further comprising;
a cooling manifold that is in fluid communication with the transport tray and a gas source; and
an electrostatic chuck coupled to the transport tray, the electrostatic chuck being opposite the patterned package support.

20. An apparatus for EMI shielding of an electronic package, comprising:
a transport tray;
a plurality of microelectronic devices arranged around the transport tray;
a patterned package support disposed between the transport tray and the microelectronic devices, the patterned package support comprising:
a core carrier layer having a first surface and a second surface,
an adhesion layer disposed on the first surface;
a conductive layer disposed on the second surface, the conductive layer, the adhesion layer, and the core carrier layer being in fluid communication with the microelectronic devices and the transport tray, wherein the conductive layer comprises a thickness between 0.01 μm and 0.5 μm; and
an electrostatic chuck disposed between the conductive layer and the transport tray.
